(19) United States
(12) Patent Application Publication
(10) Pub. No.: US 2026/0253655 A1
(43) Pub. Date: Aug. 27, 2026

(54) ELECTRIC FUSE MEMORY AND POWER SWITCH CIRCUIT ARRANGEMENT

(71) Applicant: Infineon Technologies Austria AG, Villach (AT)

(72) Inventors: Guillermo Alejandro Conde Guerra, Velden (AT); Daniele Miatton, Carbonara al Ticino PV (IT); Igor Ullmann, Villach (AT); Stefan Manfred Lindermaier, Muenchen (DE)

(21) Appl. No.: 19/542,451

(22) Filed: Feb. 17, 2026

(30) Foreign Application Priority Data
Feb. 21, 2025 (DE) 102025106608.6

(51) Int. Cl. G11C 17/18; G11C 17/16

(52) U.S. Cl. CPC G11C 17/18; G11C 17/16

(57) ABSTRACT

Various aspects of this disclosure provide an electric fuse memory and a power switch circuit arrangement. The electric fuse memory may include a plurality of memory cell blocks, each memory cell block of the plurality of memory cell blocks comprising a plurality of electric fuse memory cells; a pointer circuit configured to access one or more electric fuse memory cells of all memory cell blocks of the plurality of memory cell blocks; and a control circuit configured to control access to the plurality of electric fuse memory cells of all memory cell blocks of the plurality of memory cell blocks, using the pointer circuit to access the one or more electric fuse memory cells to access.

### TECHNICAL FIELD

Various aspects of this disclosure relate generally to an electric fuse memory and a power switch circuit arrangement.

### BACKGROUND

Silicon Carbide (SiC) switch devices (e.g. SiC power switch devices) can operate at very high switching speeds. This rapid switching can make short circuit detection difficult because an associated protection circuitry must be able to respond extremely quickly to prevent damage to the device. The speed at which a protective response is initiated is critical in preventing permanent damage.

Solutions where the protection is handled by the external components such as gate drivers, do not guarantee sufficiently fast detection and reaction times. Thus, the integration of a so-called companion integrated circuit (IC) with the power switch device is conventionally provided to handle these demanding timing constraints.

Accurately setting thresholds for current or voltage that indicate a short circuit is non-trivial. If the threshold is set too low, the system might be too sensitive and generate false positives; if it is set too high, it might miss actual short circuits.

Variations in the manufacturing process of a SiC power switch device may lead to inconsistencies in their ability to handle short circuit conditions. This variability can further complicate the detection and management of such events.

In order to adjust the threshold settings, compensate for process variations and configure the timings of the detection and reaction parameters the inclusion of memory elements in the companion IC is desired. The read-out of such a memory is performed at very high speed. The implementation shall consider also the strict power consumption limitations required by these companion ICs, which lack a dedicated supply pin.

### SUMMARY

Various aspects of this disclosure provide an electric fuse memory. The electric fuse memory may include a plurality of memory cell blocks, each memory cell block of the plurality of memory cell blocks including a plurality of electric fuse memory cells, a pointer circuit configured to address one or more electric fuse memory cells of all memory cell blocks of the plurality of memory cell blocks, and a control circuit configured to control access to the plurality of electric fuse memory cells of all memory cell blocks of the plurality of memory cell blocks, using the pointer circuit to address the one or more electric fuse memory cells to access.

Various aspects of this disclosure provide a power switch circuit arrangement. The power switch circuit arrangement may include a power switch circuit; a circuit configured to control the power switch circuit; and an electric fuse memory described above.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a power switch circuit arrangement in accordance with various aspects of this disclosure;

FIG. 2 shows a power switch circuit in accordance with various aspects of this disclosure;

FIG. 3 shows another power switch circuit in accordance with various aspects of this disclosure;

FIG. 4 shows a portion of an integrated circuit of the power switch circuit arrangement in accordance with various aspects of this disclosure;

FIG. 5 shows an electric fuse memory in accordance with various aspects of this disclosure;

FIG. 6 shows an electric fuse memory cell in accordance with various aspects of this disclosure;

FIG. 7 shows an electric fuse memory in accordance with various aspects of this disclosure;

FIG. 8 shows a portion of an electric fuse memory in accordance with various aspects of this disclosure;

FIG. 9 shows the portion of an electric fuse memory of FIG. 8 illustrating a built-in self-test in accordance with various aspects of this disclosure;

FIG. 10 shows an electric fuse memory in accordance with various aspects of this disclosure;

FIG. 11 shows an electric fuse memory in accordance with various aspects of this disclosure; and

FIG. 12 illustrates an electric fuse memory access across a plurality of memory words in accordance with various aspects of this disclosure.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects provide a circuit which is e.g. able to speed up by ~16 times the read-out of an electric fuse (eFuse) memory cell (compared with conventional solutions) while reducing area and power consumption. Various aspects are based on a pipeline system with a pointer which is used for sensing and controlling purposes as well.

The memory architecture in accordance with various aspects differ from conventional matrix-based structures: with this concept the word size may be adapted to the exact number of bits needed, thereby increasing the sensing speed.

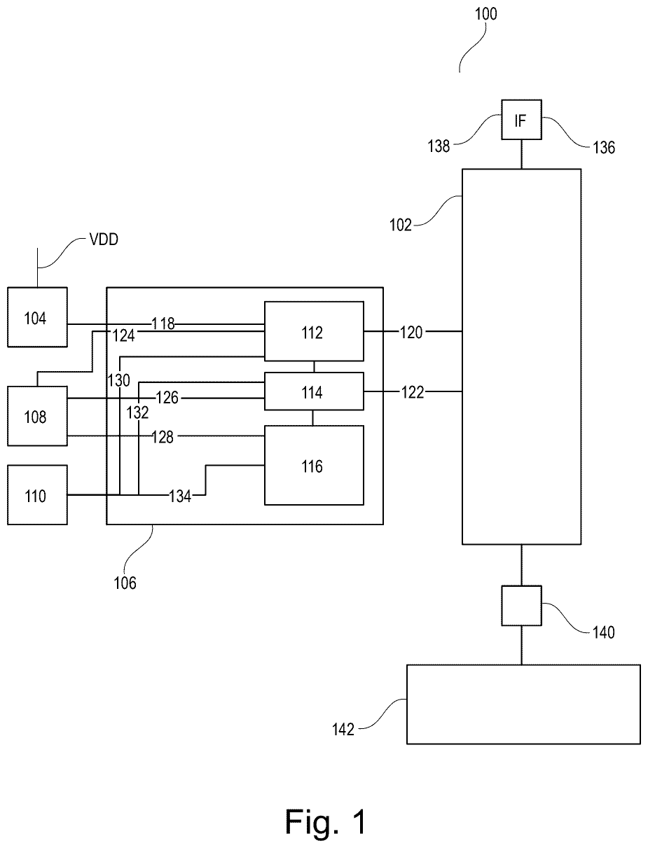

FIG. 1 shows a power switch circuit arrangement 100 in accordance with various aspects of this disclosure. The power switch circuit arrangement 100 may include a power switch circuit 102, a gate driver 104, an integrated circuit (IC) 106 (which may also be referred to as a companion IC 106), a timer circuit 108, and a power management unit 110. The IC 106 may include a gate control circuit 112, a current sense circuit 114, and an electric fuse (eFuse) memory 116.

As will be described in more detail below, the power switch circuit 102 may include one or more power switch devices such as one or more power transistors. The one or more power transistors may be configured as one or more power bipolar transistors, one or more power insulated gate bipolar transistor (IGBT) or one or more power field effect transistors (FETs), e.g. one or more power metal oxide semiconductor (MOS) FETs. The one or more power MOSFETs may be configured as one or more n-channel power MOSFETs (power NMOSFETs) or as one or more p-channel power MOSFETs (power PMOSFETs). The one or more power MOSFETs may be configured as IV (e.g. silicon (Si)) power MOSFETs) or as IV-IV compound (e.g. silicon carbide (SiC) power MOSFETs) or as other binary or ternary compound semiconductor power MOSFETs (e.g. III-V-power MOSFETs such as gallium nitride (GaN) power MOSFETs, and the like).

The power switch circuit 102 is configured to switch high voltages and currents. During operation, a short circuit may occur, which may lead to a strongly increased load current through the power switch circuit 102, which may damage or even destroy the power switch circuit 102. Therefore, a fast and secure protection measure, such as switching off of the power switch circuit 102, is desired. The faster the power switch circuit 102 can switch, the more important it becomes that the power switch circuit 102 can be deactivated in a very short time after the short circuit event occurs. By way of example, in case the power switch circuit 102 includes or is formed by a SiC power MOSFET, a time duration in the range of tens of nanoseconds or in the range of single digit nanoseconds may be desired.

The gate driver 104 provides a gate driver signal 118 to the IC 106 and within the IC106 to the gate control circuit 112, which controls the switching of the power switch circuit 102 by applying a gate control signal 120 to a control terminal of the power switch device of the power switch circuit 102, thereby controlling a current flow through the power switch device, as will be described in more detail below.

The IC 106 (which may also be referred to as a companion IC 106) is configured to protect the power switch circuit 102, e.g. in case a short circuit event occurs. The IC 106 is configured to receive a power switch current signal 122 from the power switch circuit 102. The power switch current signal 122 is representative of a current flowing e.g. through the power switch device of the power switch circuit 102. If the power switch current signal 122 exceeds a predetermined threshold, thereby indicating an overcurrent or short circuit event in the power switch circuit 102, the IC 106 may control the gate control signal 120, e.g. by reducing the voltage or current of the gate control signal 120 or even by switching the gate control signal 120 off (i.e. reducing the voltage or current of the gate control signal 120 to zero (Volts or Ampere). It is to be noted that the companion IC 106 may be included in the same package (in other words in the same housing) as the power switch circuit 102 and that the only external terminal of such an arrangement may be one or more load terminals, a gate terminal and an auxiliary source/emitter terminal.

It is further to be noted that in various aspects, the term “short circuit” is used to indicate any kind of overcurrent condition in the power switch.

Furthermore, optionally, the timer circuit 108 may be provided. The timer circuit 108 may be configured to generate and provide one or more timing signals (e.g. clock signals) to the electronic components of the IC 106. By way of example, the timer circuit 108 may be configured to provide a first clock signal 124 to the gate control circuit 112, a second clock signal 126 to the current sense circuit 114, and a third clock signal 128 to the eFuse memory 116. The first clock signal 124, the second clock signal 126 and the third clock signal 128 may be the same clock signal or may be different clock signals, i.e. they may have different timings or the same timing (time and/or phase of the pulses of the clock signals). It is to be noted that the respective timing (clock) signals may also be provided by one or more external devices (external to the power switch circuit arrangement 100) such as one or more external oscillator circuits (not shown).

Moreover, optionally, the power switch circuit arrangement 100 may include the power management unit 110. The power management unit 110 may be configured to provide respective operating voltages 130, 132, 134 to the electronic components of the IC 106. By way of example, the power management unit 110 may be configured to provide a first operating voltage 130 to the gate control circuit 112, a second operating voltage 132 to the current sense circuit 114, and a third operating voltage 134 to the eFuse memory 116. The first operating voltage 130, the second operating voltage 132 and the third operating voltage 134 may be the same operating voltage or may be different operating voltages. It is to be noted that the respective operating voltages may also be provided by one or more external devices (external to the power switch circuit arrangement 100) such as one or more external power supplies. In one or more embodiments, the power management unit 110 may also be included in the same package together with the power switch circuit 102 and companion IC 106. In such an arrangement, the power management unit 110 may be configured for providing the respective operating voltages based on electrical energy that is provided with the gate driver signal 118.

The power switch arrangement 100 may be coupled between interface pads 136 and 140 to control a flow of electrical energy therebetween. The interface pads 136 and 140 may also be referred to as load nodes. For example, when the power switch circuit 102 includes a MOSFET the interface pad 136 may be coupled to a drain of the MOSFET, and the interface pad 140 may be coupled to a source of the MOSFET. For example, the interface pad 136 may be coupled to a positive direct current (DC) supply rail, and an external load circuit 142 may be coupled to the interface pad 140. Thus, in this arrangement, the power switch circuit 102 forms a high-side switch. However, this is just an example, and other arrangements are possible. For example, the power switch circuit 102 may be arranged as a low-side switch (e.g., when the interface pad 136 is coupled to the load and the interface pad 140 is coupled to a ground or negative DC supply rail).

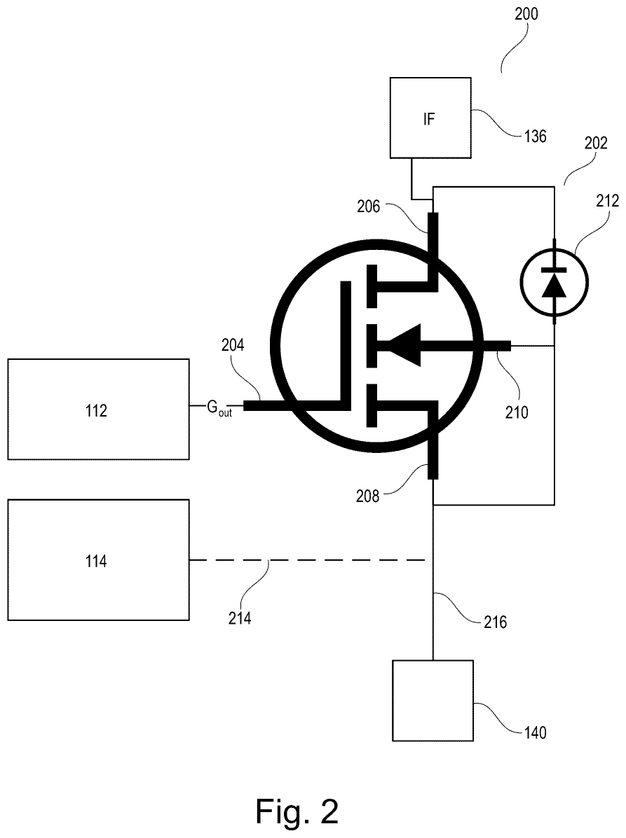

FIG. 2 shows a power switch circuit 200 in accordance with various aspects of this disclosure. The power switch circuit 200 is one exemplary implementation of the power switch circuit 102 of FIG. 1. The power switch circuit 200 may include or essentially consist of a power MOSFET 202, e.g. a power NMOSFET 202, e.g. a power SiC NMOSFET 202. The power NMOSFET 202 includes a gate terminal 204, a drain terminal 206, a source terminal 208 and a substrate terminal 210. The gate terminal 204 may be coupled to the gate control circuit 112, the drain terminal 206 may be coupled to the interface pad 136, and the source terminal 208 may be coupled to the further interface pad 140, and via the further interface pad 140, e.g. with the external load circuit 142. The source terminal 208 may further be coupled to the substrate terminal 210 and (via e.g. a body diode 212 of the NMOSFET 202) to the drain terminal 206 and the interface pad 136. In this example, the current sense circuit 114 receives an electric sense current (e.g. a current representative of the source current) 214 representative of an electric current 216 flowing through the power NMOSFET 202 from the drain terminal 206 (i.e. the current flowing from the interface pad 136) to the source terminal 208 and processes the received electric sense current 214 as will be described in more detail below. The gate control circuit 112 is configured to provide the gate control signal 120 to the gate terminal 204 to modulate the gate voltage of the power NMOSFET 202 to thereby control the current 216 flowing through the power NMOSFET 202 from the drain terminal 206 to the source terminal 208 (illustratively, e.g. to switch the power NMOSFET 202 on or off). By way of example, the electric sense current 214 may be derived from the electric current 216 using a current mirror or any other suitable circuit or measurement device to determine a current representative for the electric current 216.

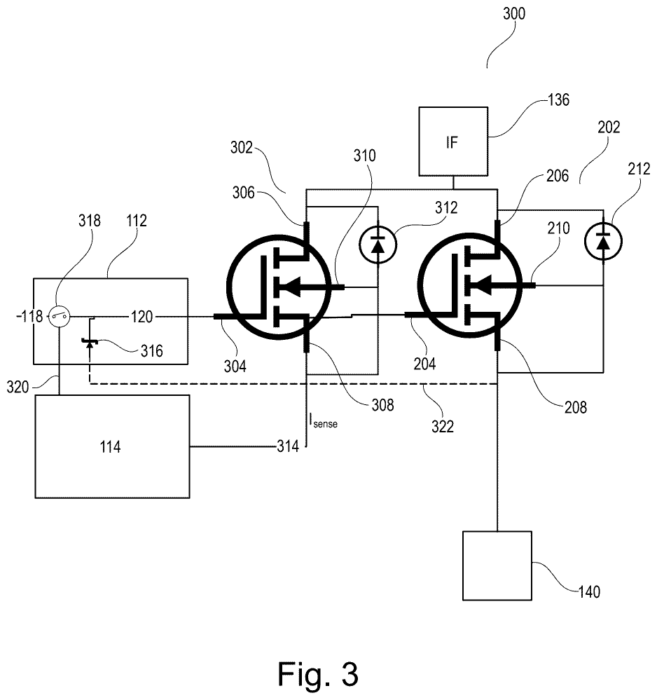

FIG. 3 shows a power switch circuit 300 in accordance with various aspects of this disclosure. The power switch circuit 300 is another exemplary implementation of the power switch circuit 102 of FIG. 1. The power switch circuit 300 may include, in addition to the power NMOSFET 202 of FIG. 2, a sense power MOSFET 302, e.g. a sense power NMOSFET 302, e.g. a sense power SiC NMOSFET 302. The sense power NMOSFET 302 includes a gate terminal 304, a drain terminal 306, a source terminal 308 and a substrate terminal 310. The sense power NMOSFET 302 may be monolithically integrated with the power NMOSFET 202. For example, a total active area may include a plurality of transistor cells arranged on a single substrate, and the sense power NMOSFET 302 is formed by a fraction, for example between 1% to 25%, of all transistor cells, while the remaining cells form the power NMOSFET 202. The gate terminal 304 may be coupled to the gate control circuit 112, the drain terminal 306 may be coupled to the interface pad 136, and the source terminal 308 may be coupled to the current sense circuit 114. It is to be noted that in this example the source terminal 208 of the power NMOSFET 202 is not coupled to the current sense circuit 114 but to the gate control circuit 112, as will be described in more detail below. The source terminal 308 of the sense power NMOSFET 302 may further be coupled to the substrate terminal 310 and (via e.g. a body diode 312 of the sense power NMOSFET 302) to the drain terminal 306 and the interface pad 136. In this example, the current sense circuit 114 receives an electric current (e.g. the source current) 314 flowing through the sense power NMOSFET 302 from the drain terminal 306 (i.e. the current flowing from the interface pad 136) to the source terminal 308 and processes the received current 314 as will be described in more detail below. The gate control circuit 112 is configured to provide the gate control signal 120 also to the gate terminal 304 of the sense power NMOSFET 302 to modulate the gate voltage of the sense power NMOSFET 302 to thereby control the current flowing through the sense power NMOSFET 302 from the drain terminal 306 to the source terminal 308 (illustratively, e.g. to switch the sense power NMOSFET 302 on or off).

In an example, the gate control circuit 112 may include a clamping structure (e.g. including or consisting of a clamping diode) 316 and a switch 318. The IC 106 may control the clamping structure 316 in case of a detected overcurrent.

A first terminal of the clamping structure 316 is coupled to the source terminal 208 of the power NMOSFET 202 to provide a gate current discharge path 322: When the current sense circuit 114 triggers based on an overcurrent, the gate (and thus the gate terminal 204) of the power NMOSFET 202 should be discharged to protect the power NMOSFET 202. This current can only flow to the source (and thus to the source terminal 208) of the power NMOSFET 202 (since the gate voltage to control the switch is the voltage between the gate terminal and the source terminal of a power switch). A second terminal of the clamping structure 316 is coupled to a second terminal of the switch 318 and to the gate terminal 204 of the power NMOSFET 202 and to the gate terminal 304 of the sense power NMOSFET 302. A first terminal of the switch 318 is coupled to the gate driver 104 to receive the gate driver signal 118 therefrom.

Illustratively, there are similar current densities in the active area of the power NMOSFET 202 and the sense power NMOSFET 302, since the drain terminal 206 of the power NMOSFET 202 and the drain terminal 306 of the sense power NMOSFET 302 are both directly coupled to each other and to the interface pad 136. In other words, in this “dual source solution”, the sense power NMOSFET 302 is used to sense the electric current flowing through the power switch (i.e. the power NMOSFET 202 in this example) itself.

The operation of the gate control circuit 112 and the current sense circuit 114 is as follows:
The current sense circuit 114 is configured to, in a detection phase, sense the current flowing through the sense power NMOSFET 302 (i.e. the source current 314 Iₛₑₙₛₑ flowing through the sense power NMOSFET 302) and compare it with a pre-defined short-circuit threshold I_{th,sc} (as will be explained in more detail below); the current sense circuit 114 is configured to detect a short circuit or overcurrent event in case it is determined that the sensed source current 314 Iₛₑₙₛₑ is greater than the pre-defined short-circuit threshold I_{th,sc} (Iₛₑₙₛₑ>I_{th,sc}).

It is to be noted that the current sensing may be provided in other suitable ways (not limited to using a sense transistor as in the example of FIG. 3), such as using magnetic sensors (Hall effect) or shunt resistor or any other kind of current measurement suitable for measuring the load current through the power MOSFET 202.
The gate control circuit 112 is configured to, in case of a short circuit event detected e.g. by the current sense circuit 114:
in a first phase, move the gate control signal 120 (e.g. the gate voltage 120 of the power NMOSFET 202) to a pre-defined clamping voltage V_{clamp} (using the clamping structure 316) in a controlled way so that the electric current flowing through the power switch (e.g. the power NMOSFET 202) is limited or reduced, while ensuring that the drain-source voltage V_{ds} across the power switch (e.g. the power NMOSFET 202) does not exceed a maximum allowed upper threshold voltage during the limiting operation such as, e.g., a maximum voltage blocking capability of the power NMOSFET 202 (e.g. for an SiC power MOSFET) V_{ds,maxSiC} (of e.g. 1200 V);
in a second phase, keep the gate control signal 120 (e.g. the gate voltage 120 of the power NMOSFET 202) constant at the pre-defined clamping voltage V_{clamp} (using the clamping structure 316) for a pre-defined time duration (in this phase, the gate control circuit 112 may open its switch 318 so that the gate driver signal 118 is not forwarded to the gate terminal 204 of the power NMOSFET 202); and
in a third phase, reduce the gate control signal 120 (e.g. the gate voltage 120 of the power NMOSFET 202) to a voltage lower than a threshold voltage V_{SiCmin} of the power NMOSFET 202, in other words, deactivate (turn off) the power switch (e.g. the power NMOSFET 202); it is to be noted that also in this phase, the gate control circuit 112 keeps its switch 318 open so that the gate driver signal 118 is not forwarded to the gate terminal 204 of the power NMOSFET 202).
In various aspects of this disclosure, either the second phase or the third phase may be omitted.

It is to be noted that the current sense circuit 114 is configured to, in case it determines a short circuit event, generates a gate switch control signal 320 and applies the same to the switch 318 to open the switch during the above-described second phase and third phase.

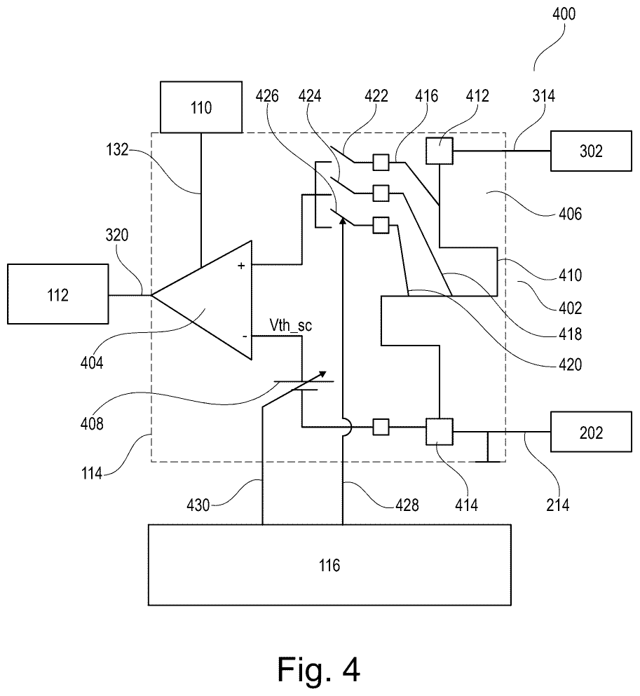

FIG. 4 shows a portion 400 of the IC 106 of the power switch circuit arrangement 100 in accordance with various aspects of this disclosure in a power up state.

As shown in FIG. 4, the IC 106 may include the current sense circuit 114. The current sense circuit 114 may include a current-voltage transducer 402. The current-voltage transducer 402 may include a comparator 404. A non-inverting input of the comparator 404 is coupled to the source terminal 308 of the sense power NMOSFET 302 via a trimmable (in other words adjustable) shunt resistance 406 and an inverting input of the comparator 404 is coupled to the source terminal 208 of the power NMOSFET 202 via a trimmable (in other words adjustable) voltage source 408. The shunt resistance 406 may include a metal line 410 extending from a first node 412, which is coupled to the source terminal 308 of the sense power NMOSFET 302, to a second node 414, which is coupled to the source terminal 208 of the power NMOSFET 202. A plurality of separate metal connections 416, 418, 420 may be connected to different locations of (in other words along) the metal line 410 (e.g. such that several different voltage dividers are effectively created by the arrangement), each of the metal connections 416, 418, 420 is switchably coupled to the non-inverting input of the comparator 404 via respectively associated switches 422, 424, 426. The switches 422, 424, 426 may thus enable to control the voltage to be provided to the non-inverting input of the comparator 404 from the metal line 410 of the shunt resistance 406. As will be described in more detail below, the content of electric fuse (eFuse) memory cells of the eFuse memory 116 may control the state of the switches 422, 424, 426 and the trimmable voltage source 408. In other words, the content of (e.g. some of) the eFuse memory cells of the eFuse memory 116 sets the state of the switches 422, 424, 426 and the trimmable voltage source 408. To do this, the memory (e.g. associated eFuse memory cells of the eFuse memory 116) may be coupled via one or more switch control lines 428 to the switches 422, 424, 426 and via one or more voltage source control lines 430 to the trimmable voltage source 408. The setting may be provided at a power up period or during the operation of the IC 106 of the power switch circuit arrangement 100. Therefore, it is important that the eFuse memory 116 has a very short read-out time to provide the setting parameters (i.e. the respective control signals) to the trimmable components of the current sense circuit 114. It is to be noted that also other electronic components of the current sense circuit 114 may be trimmable and controlled via respectively associated eFuse memory cells of the eFuse memory 116. Furthermore, it is to be noted that also other electronic components of the IC 106 may be trimmable and controlled via respectively associated eFuse memory cells of the eFuse memory 116. By way of example, a trimming of the gate control circuit 112 may be provided.

By way of example, trimming may serve the purpose to adapt the IC 106, e.g. the current sense circuit 114, to the characteristics of different transistor types, e.g. to different SiC transistor families and manufacturing process variations.

In case of a short circuit event, the current flowing through the sense power NMOSFET 302 raises very fast and thus the source current 314 Iₛₑₙₛₑ flowing through the sense power NMOSFET 302 flows through the shunt resistance 406, thereby causing an increase of the voltage applied to the non-inverting input of the comparator 404. When the voltage applied to the non-inverting input of the comparator 404 becomes greater than a reference voltage applied to the inverting input of the comparator 404 by the trimmable voltage source 408, the comparator 404 switches from a first logic state to a second logic state. In this case, the comparator 404 generates the gate switch control signal 320 and applies the same to the switch 318 to open the switch 318 during the above-described second phase and third phase.

The trimming of various electronic components of the current sense circuit 114 may set a tripping threshold at a desired temperature, e.g. at ambient temperature.

The trimming of the electronic components of the current sense circuit 114 should be carried out as fast as possible to ensure that there is a negligible impact on the wake-up time of the IC 106 and to avoid a false short circuit detection.

In the following, various exemplary implementations will be described which improve the speed of an access to the content of an eFuse memory cell of the eFuse memory 116.

As will be described in more detail below, the eFuse memory 116 may include one or more memory cell blocks, each memory cell block including a plurality of eFuse memory cells.

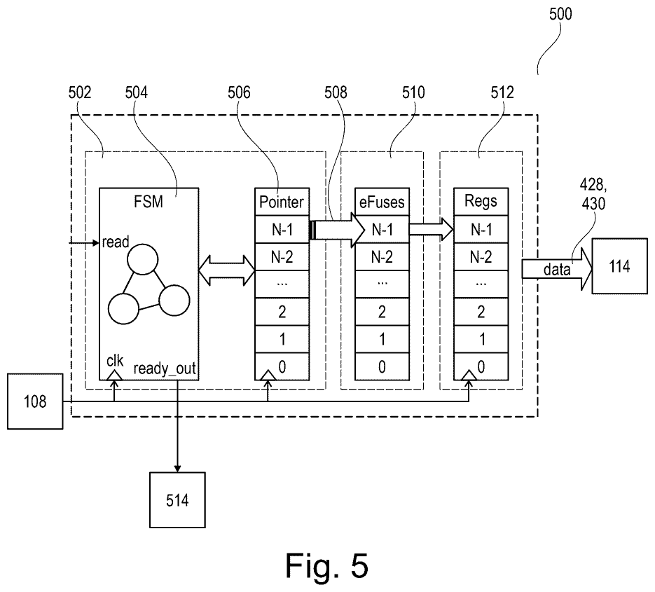

FIG. 5 shows an eFuse memory 500 in accordance with various aspects of this disclosure. The eFuse memory 500 is an exemplary implementation of the eFuse memory 116 of FIG. 1.

The eFuse memory 500 may include a controller 502, e.g. any kind of logic (programmable or hard-wired), configured to control access to eFuse memory cells of one or more memory cell blocks. The controller 502 may include a control circuit 504 implementing a finite state machine (FSM) configured to control the type of access to the eFuse memory cells such as a programming access (e.g. to blow an electric fuse of a respective eFuse memory cell) or a sense access (e.g. to sense a current flowing through an eFuse line of a respective eFuse memory cell). By way of example, the controller 502 may be configured to provide one or more voltages to program or read one or more eFuse memory cells and the corresponding timing of the programming process to program one or more eFuse memory cells and the reading process to read one or more eFuse memory cells.

The controller 502 may further include a pointer circuit 506 configured to provide an address signal 508 to activate one or more memory cells to be accessed in accordance with the type of access controlled by the control circuit 504 at the same time. The pointer circuit 506 may include or consist of a shift register. The shift register may include a plurality of serially connected registers, e.g. flip flops, e.g. D flip flops, e.g. edge triggered D flip flops. It is to be noted that the registers of the shift register may be implemented by any other type of flip flop, if desired. An output of a respective register may activate (and thereby access) a single associated eFuse memory cell (or a plurality of associated eFuse memory cells as will be described in more detail below).

The eFuse memory 500 may further include one or more memory cell blocks, each memory cell block including a plurality of eFuse memory cells 510. The eFuse memory 500 may further include a plurality of registers 512, e.g. implemented by a plurality of flip flops (e.g. D flip flops, e.g. edge triggered D flip flops). It is to be noted that the flip flops may be implemented by any other type of flip flop, if desired. The plurality of registers 512 may e.g. contain soft registers into which the content of the eFuse memory cell is loaded and displayed.

Each register of the plurality of registers 512 may include one or more flip flops. Each register of the plurality of registers 512 may be provided for a respectively associated trimmable electronic components, e.g. trimmable electronic components of the current sense circuit 114, as described above. By way of example, one register may include three flip flops storing control information to control the switches 422, 424, 426 (e.g. after the eFuse read-out). Another register may include one or more flip flops storing control information to control the trimmable voltage source 408 (in such a case, the number of flip flops is dependent on the desired control resolution of the trimmable voltage source 408).

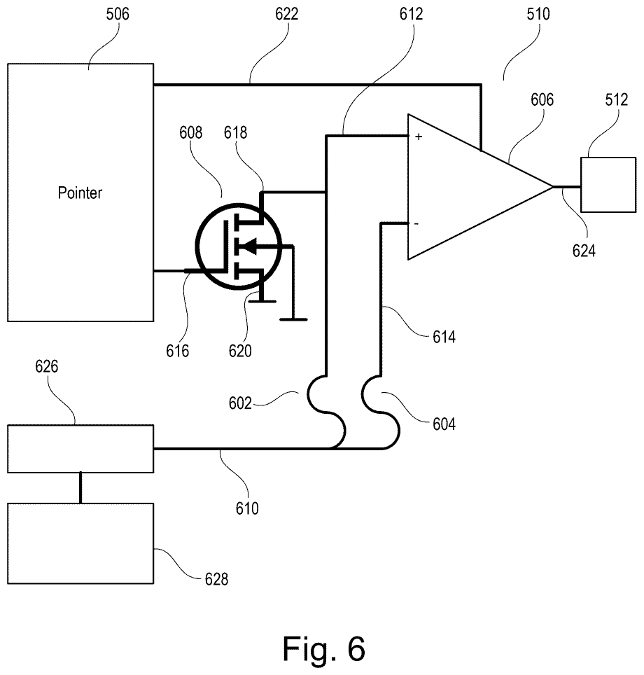

FIG. 6 shows an example of an electric fuse (eFuse) memory cell 510 of the plurality of eFuse memory cells 510 in accordance with various aspects of this disclosure.

The eFuse memory cell 510 may include:
an electric fuse (eFuse) structure 602;
an electric fuse (eFuse) reference structure 604;
a sense amplifier 606;
a blow transistor 608 (e.g. a MOSFET, e.g. an NMOSFET).

It is to be noted that the eFuse memory cell may have a different structure and different components, as long as it includes an electric fuse (eFuse) and a read-out component and is thus a one-time programmable (OTP) memory cell. The eFuse memory cell may be configured to permanently store a (e.g. logic) value representing the state of the eFuse. The eFuse memory cell may be programmable (the eFuse memory may be configured to program the eFuse memory cell e.g. by blowing (melting) the eFuse of the eFuse memory cell). The eFuse memory cell may further be configured to provide a value indicating the state of the eFuse to an eFuse memory cell external circuit, e.g. to an associated register of the plurality of registers 512.

A first end of the eFuse structure 602 may be connected to a voltage source 626 via a first connection 610 (e.g. a first metal line). The voltage source 626 may be part of or external to the power switch circuit arrangement 100. The voltage source 626 may be configured to provide different voltages to the eFuse structure 602 and to the eFuse reference structure 604 depending e.g. on the operation mode of the eFuse memory 116. By way of example, in a first operation mode (e.g. a programming mode) of the eFuse memory 116, the voltage provided by the voltage source 626 may be sufficiently high to damage (e.g. melt or blow) the eFuse structure 602 and, in a second operation mode (e.g. a read mode) of the eFuse memory 116, the voltage provided by the voltage source 626 may be sufficient to determine the state of the eFuse structure 602 (representing the content of the respective eFuse memory cell 510) without damaging the eFuse structure 602. The power switch circuit arrangement 100 may include a voltage source control pad 628 to allow a user to select the first operation mode (e.g. a programming mode) of the eFuse memory 116 or the second operation mode (e.g. a read mode) of the eFuse memory 116 and thereby to control the voltage source 628 to provide the respectively required voltage to the eFuse memory cell 510 selected by the pointer circuit 506. An opposite second end of the eFuse structure 602 may be connected to the sense amplifier 606 (e.g. to a non-inverting input of the sense amplifier 606) via a second connection 612 (e.g. a second metal line).

A first end of the eFuse reference structure 604 may be connected to the voltage source 626 via the first connection 610 (e.g. the first metal line) and an opposite second end of the eFuse reference structure 604 may be connected to the sense amplifier 606 (e.g. to an inverting input of the sense amplifier 606) via a third connection 614 (e.g. a third metal line). The sense amplifier 606 is an exemplary implementation of a portion of a read circuit configured to read the content of the accessed one or more eFuse memory cells. The read circuit may further include a plurality of output registers (e.g. the registers 512) configured to store the content of the accessed one or more eFuse memory cells 510.

An output of the sense amplifier 606 may be coupled to an associated register 512 (e.g. to an associated flip flop, e.g. to a D-input of a D flip flop of the register 512).

Moreover, the pointer circuit 506 may be coupled to a control input 616 of the blow transistor 608 (e.g. to a gate terminal of a MOSFET implementing the blow transistor 608). A first controlled input 618 of the blow transistor 608 (e.g. a drain terminal of the MOSFET implementing the blow transistor 608) may be coupled to the second connection 612 (e.g. to a node located between the second end of the eFuse structure 602 and the non-inverting input of the sense amplifier 606). A second controlled input 620 of the blow transistor 608 (e.g. a source terminal of the MOSFET implementing the blow transistor 608) may be coupled to a reference potential (e.g. ground potential). Furthermore, the pointer circuit 506 may be coupled to the sense amplifier 606 via a control line 622 to selectively activate or deactivate the sense amplifier 606.

In order to blow (in other words melt, in general destroy) (in this case, the control circuit 504 operates in a programming mode) the eFuse structure 602, the control circuit 504 may deactivate the sense amplifier 606 (via a corresponding selection by the pointer circuit 506) and close the blow transistor 608 to allow a blow current flow through the blow transistor 608. The blow current (provided by the voltage source 626) is selected to be sufficiently high to blow (destroy) the eFuse structure 602. The pointer circuit 506 selects the memory cell 510 to be programmed. In various aspects of this disclosure, the pointer circuit 506 may be configured to subsequently address one or more eFuse memory cells of one or more memory cell blocks.

Furthermore, in order to read the content of a respective memory cell 510 (in this case, the control circuit 504 operates in a read mode), the controller 502 may activate the sense amplifier 606 (e.g. via the pointer circuit 506) and open the blow transistor 608 (to prevent a current flow through the blow transistor 608) and the voltage source 626 may provide a read current flowing through the first connection 610. Thus, a first current representing the read current flows through the eFuse reference structure 604 to the inverting input of the sense amplifier 606. Furthermore, the non-inverting input of the sense amplifier 606 receives a second current representing the status of the eFuse structure 602 (if the eFuse structure 602 is not fused (blown), the non-inverting input of the sense amplifier 606 receives the second current via the eFuse structure 602 and the first connection 610; if the eFuse structure 602 is programmed (e.g. fused or blown), the non-inverting input of the sense amplifier 606 receives a current of substantially zero, i.e. a current that is substantially lower than the first current). It is to be noted that the eFuse reference structure 604 may be configured such that the first current is lower than the second current in case the eFuse structure 602 is not fused. Thus, illustratively, the sense amplifier 606 may be configured to provide a memory cell state signal 624 to the one or more registers 512, more accurately to an associated flip flop of a register of the plurality of registers 512). The memory cell state signal 624 may have a first signal state (e.g. by providing a first logic value) indicating that the eFuse structure 602 is not programmed (e.g. not fused) and a second signal state (e.g. by providing a second logic value different from the first logic value) indicating that the eFuse structure 602 is programmed (e.g. fused). The associated flip flop of a register of the plurality of registers 512 stores the memory cell state signal 624.

In this way, the plurality of registers 512 may store the memory cell state signals 624, in other words, the content of the eFuse memory cells 510. The plurality of registers 512 may be configured to provide the memory cell state signals 624 to the trimmable electronic components of the IC 106, e.g. to the trimmable electronic components of the current sense circuit 114, as described above.

By way of example, one or more of the eFuse memory cells 510 may include a content representing a state of a control signal to control a switch 422, 424, 426 of the plurality of switches 422, 424, 426 associated with the respective eFuse memory cell 510. Illustratively, a first logic value (e.g. logic “0”) stored in one (e.g. a first) eFuse memory cell of the plurality of eFuse memory cells 510 may represent a state of a control signal to open a first switch 422 of the plurality of switches 422, 424, 426 and a second logic value (e.g. logic “1”) stored in the first eFuse memory cell of the plurality of eFuse memory cells 510 may represent a state of the control signal to close the first switch 422. Correspondingly, a first logic value (e.g. logic “0”) stored in another (e.g. a second) eFuse memory cell of the plurality of eFuse memory cells 510 may represent a state of a control signal to open a second switch 424 of the plurality of switches 422, 424, 426 and a second logic value (e.g. logic “1”) stored in the other (e.g. second) eFuse memory cell of the plurality of eFuse memory cells 510 may represent a state of the control signal to close the second switch 424. Furthermore, a first logic value (e.g. logic “0”) stored in third eFuse memory cell of the plurality of eFuse memory cells 510 may represent a state of a control signal to open a third switch 426 of the plurality of switches 422, 424, 426 and a second logic value (e.g. logic “1”) stored in the third eFuse memory cell of the plurality of eFuse memory cells 510 may represent a state of the control signal to close the third switch 426.

The content of these eFuse memory cells may be read and an associated one of the plurality of sense amplifiers 606 may be configured to provide a logic value representing the content of the associated eFuse memory cell to an associated flip flop of the register of the plurality of registers 512 (in an example, exactly one flip flop may be associated and connected with exactly one sense amplifier and exactly one sense amplifier may be provided for exactly one eFuse memory cell). It is to be noted that in various aspects, a plurality of eFuse memory cells may share an associated sense amplifier (in such a case, a time multiplexed reading of these eFuse memory cells is provided). Each flip flop of a register 512 of the plurality of registers 512 may be coupled to the respective switch 422, 424, 426 via the one or more switch control lines 428.

Moreover, a fourth eFuse memory cell (or a plurality of eFuse memory cells) may include a content representing a state of a control signal to control the trimmable voltage source 408 associated with the respective eFuse memory cells 510. Illustratively, a first logic value (e.g. logic “0”) stored in one (e.g. a fourth) eFuse memory cell of the plurality of eFuse memory cells 510 may represent a state of a control signal to set the trimmable voltage source 408 to a first state (providing a first voltage) and a second logic value (e.g. logic “1”) stored in the fourth eFuse memory cell of the plurality of eFuse memory cells 510 may represent a state of the control signal to set the trimmable voltage source 408 to a second state (providing a second voltage different from the first voltage).

The content of the fourth eFuse memory cell may be read and an associated one of the plurality of sense amplifiers 606 may be configured to provide a logic value representing the content of the associated fourth eFuse memory cell to an associated flip flop of a (voltage source control) register of the plurality of registers 512 (in an example, exactly one flip flop may be associated and connected with exactly one sense amplifier and exactly one sense amplifier may be provided for exactly one (e.g. the fourth) eFuse memory cell). The respective register (and the one or more flip flops of the respective (e.g. voltage source control) register) of the plurality of registers 512 may be coupled to the trimmable voltage source 408 via the one or more voltage source control lines 430. It is to be noted that, depending on the desired resolution of the trimmable voltage source 408, a plurality of corresponding eFuse memory cells, sense amplifiers and flip flops may be provided and coupled to the trimmable voltage source 408 via the one or more voltage source control lines 430.

It is to be noted that the eFuse memory 116 may include additional eFuse memory cells (e.g. eFuse memory cells 510) to store data to control or trim other electronic components of the IC 106, e.g. other electronic components of the current sense circuit 114. By way of example, a trimming of one or more of the following electronic components via the content of respectively associated eFuse memory cells (e.g. eFuse memory cells 510) may be provided:
the gate control circuit 112 to trim the gate voltage level of the gate voltage applied to the gate terminal 204;
an electronic component controlling the timing of the above described second phase;
an electronic component controlling the target voltage level of the above described second phase, e.g. the amount of current used to shut down the power switch in case of short circuit in the second phase;
an electronic component controlling the pre-defined clamping voltage V_{clamp};
an electronic component controlling a discharge current value that is used for discharging the gate of the power switch based on a maximum or desired dI/dt value (i.e. a rate of change of the load current through the power switch);
an optional power switch circuit arrangement 100 internal oscillator, e.g. the frequency generated by the oscillator;
and the like.

When the control circuit 504 has completed its read-out process, the control circuit 504 may generate a read complete signal 514 and may output the same, e.g. to an external circuit (not shown).

As will be described in more detail below, the access speed of the eFuse memory 116 may be increased in accordance with various aspects, which may be provided individually or in combination with each other.

By way of example, an improvement on the eFuse memory 116 handling may be achieved by applying one or more of the following measures:
1) Parallelizing the eFuse read-out
Increasing the number of eFuse memory cells that can be read per read cycle may speed up the read-out process. The eFuse memory 116 may provide for a read-out of a plurality of, e.g. four, eFuses memory cells per read cycle. While accessing a single eFuse memory cell per programming cycle is valid for the eFuse programming, this assumption does not prevail for sensing. As will be described in the following, a plurality of eFuse memory cells, e.g. four eFuse memory cells, can be read in parallel.
2) Smart Pipelining of the datapath 3) Hybrid centralized control

### 1) Parallelizing the eFuse Read-Out

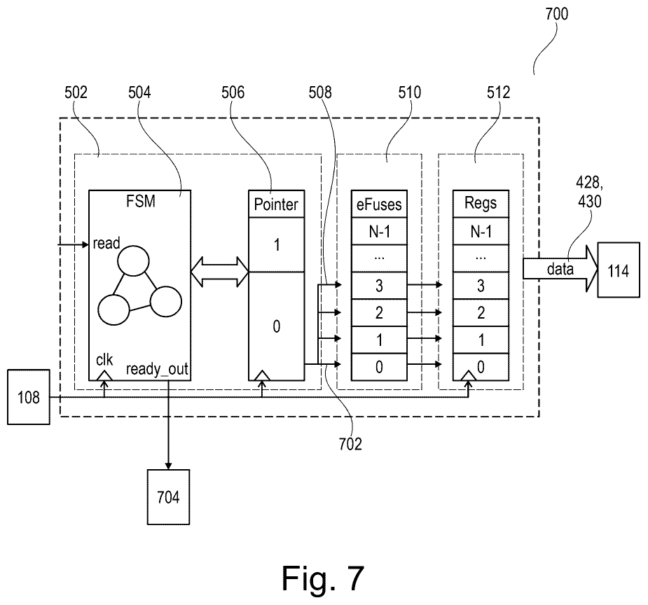

FIG. 7 shows an eFuse memory 700 in accordance with various aspects of this disclosure illustrating a parallelizing of an eFuse memory cell read-out. The eFuse memory 700 of FIG. 7 is an exemplary implementation of the eFuse memory 116 of FIG. 1.

The eFuse memory 700 of FIG. 7 is similar to the eFuse memory 500 of FIG. 5. In order to avoid repetition, only various differences of the eFuse memory 700 of FIG. 7 to the eFuse memory 500 of FIG. 5 will be described in more detail in the following. With respect to the similar components, reference is made to the above description of the eFuse memory 500 of FIG. 5.

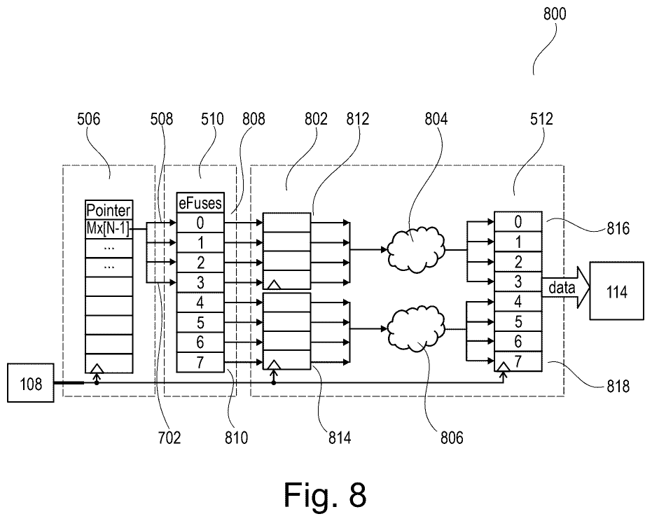

In difference to the eFuse memory 500 of FIG. 5, the pointer circuit 506 of the eFuse memory 700 of FIG. 7 is configured to address a plurality of eFuse memory cells in each memory cell block of the one or more memory cell blocks in parallel. By way of example, each output of the pointer circuit 506 (e.g. each output register of the shift register) may be coupled to a plurality of eFuse memory cells (e.g. by means of a program selection line (e.g. a single program selection line) 702 coupled to a respective output register of the shift register and to a plurality of respective program activation inputs of a plurality of (e.g. four) associated eFuse memory cells (e.g. eFuse memory cells “0”, “1”, “2”, “3” in FIG. 7) to activate/deactivate the electronic component(s) of the respective eFuse memory cell to program the respective eFuse memory cell and/or by means of a read selection line (e.g. a single read selection line) 702 coupled to a respective output register of the shift register and to a plurality of respective program activation inputs of a plurality of (e.g. four) associated eFuse memory cells (e.g. eFuse memory cells “0”, “1”, “2”, “3” in FIG. 7) to activate/deactivate the electronic component(s) of the respective eFuse memory cell to read the respective eFuse memory cell). Thus, each output of the pointer circuit 506 (e.g. each output register of the shift register may activate (i.e. access—program or read) a plurality of eFuse memory cells at the same time (in other words, in parallel). Thus, in each read cycle (e.g. in each clock cycle), a plurality of eFuse memory cells are read and their contents are stored in the associated plurality of flip flop of one or more registers of the plurality of registers 512 (e.g. flip flops “0”, “1”, “2”, “3” in FIG. 8) to be provided to the IC 106 (e.g. the current sense circuit 114).

When the control circuit 504 has completed its read-out process, the control circuit 504 may generate a read complete signal 704 and may output the same, e.g. to an external circuit (not shown).

Illustratively, in order to speed up the read-out of a plurality of eFuse memory cells, a first measure may be to increase the number of eFuse memory cells that are read in parallel.

### 2) Smart Pipelining of the Datapath

FIG. 8 shows a portion of an electric fuse memory 800 in accordance with various aspects of this disclosure. The eFuse memory 800 of FIG. 8 is an exemplary implementation of the eFuse memory 116 of FIG. 1.

The eFuse memory 800 of FIG. 8 is similar to the eFuse memory 700 of FIG. 7. In order to avoid repetition, only various differences of the eFuse memory 800 of FIG. 8 to the eFuse memory 700 of FIG. 7 will be described in more detail in the following. With respect to the similar components, reference is made to the above description of the eFuse memory 500 of FIG. 5 and to the description of the eFuse memory 700 of FIG. 7. It is to be noted that various aspects of this disclosure may also provide for a memory without a parallel access of a plurality of eFuse memory cells at the same time.

In difference to the eFuse memory 700 of FIG. 7, the eFuse memory 800 of FIG. 8 may include a plurality of intermediate registers 802 (each intermediate register 802 of the plurality of intermediate registers 802 including one or more flip flops, also referred to as one or more intermediate flip flops) coupled between the eFuse memory cells 510 and the plurality of registers 512. Each intermediate flip flop of the one or more intermediate flip flops of the plurality of intermediate registers 802 may be coupled to a single respectively associated eFuse memory cell of the plurality of eFuse memory cells 510. Each intermediate flip flop of the one or more intermediate flip flops of the plurality of intermediate register 802 may be implemented by a flip flop (e.g. D flip flop, e.g. edge triggered D flip flop). Furthermore, one or more multiplexers 804, 806 may be coupled between the plurality of intermediate registers 802 and the plurality of registers 512. It is to be noted that the one or more multiplexers 804, 806 are only an exemplary implementation. In general, instead of or in addition to the one or more multiplexers 804, 806 any combinatorial logic circuit block may be provided, also to provide some control to be able to perform both normal and fast readout of the eFuse memory cells. It is to be noted that a normal readout (a read out at a speed below the accelerated speed provided by the additional measures provided in accordance with various aspects of this disclosure) may e.g. be provided for testing purposes.

The multiplexers 804, 806 are configured to transfer the content of the plurality of intermediate registers 802 to the plurality of registers 512, e.g. in a pipelined manner. By way of example, the plurality of eFuse memory cells 510 may include eight eFuse memory cells, which may be grouped into a first group 808 of four eFuse memory cells (e.g. eFuse memory cells “0”, “1”, “2” and “3” in FIG. 8) and a second group 810 of four eFuse memory cells (e.g. eFuse memory cells “4”, “5”, “6” and “7” in FIG. 8) (it is to be noted that each group may include a different number of eFuse memory cells). Correspondingly, the plurality of intermediate registers 802 may include eight intermediate flip flops of (in this example two) intermediate registers 802, which may be grouped into a first group 812 of four intermediate flip flops of a first intermediate register 802 and a second group 814 of four intermediate flip flops of a second intermediate register 802 (it is to be noted that each group may include a different number of intermediate flip flops). The one or more multiplexers 804, 806 may be configured as n:m multiplexers (e.g. n being an integer from 1 to 4 and m being an integer from 1 to 4).

The eFuse memory cells of each group 808, 810 of eFuse memory cells are accessed in parellel by the pointer circuit 506 (via the program selection lines 702 or the read selection lines 702) and their contents are stored in the associated intermediate flip flops of a respective intermediate register of the plurality of intermediate registers 802.

A first multiplexer 804 may be coupled to the intermediate flip flops of the first group 812 of intermediate flip flops and may be configured to subsequently (in general in a pipelined manner) couple an output of an intermediate flip flop of the first group 812 of intermediate flip flops to an input of an associated (or desired) flip flop of an associated register of the plurality of registers 512.

By way of example, the plurality of flip flops of the plurality of registers 512 may include eight flip flops, which may be grouped into a first group 816 of four flip flops of a first register (e.g. flip flops “0”, “1”, “2” and “3” in FIG. 8) and a second group 818 of four flip flops of a second register (e.g. flip flops “4”, “5”, “6” and “7” in FIG. 8) (it is to be noted that each group 816, 818 may include a different number of flip flops).

In this context, it is to be noted that parallelizing the eFuse memory cell read-out would speed up the read-out of the eFuse memory cells e.g. by a factor of four in this example, as four eFuses are read out in parallel (more or less parallel read-outs are also possible).

Various aspects of this disclosure speed up the clock by pipelining the datapath of the eFuse memory 116, 800 as described above with reference to FIG. 8.

Dividing the registers into two register banks (e.g. by providing the intermediate registers 802 and the (data) registers 512) ensures that the minimum clock period corresponds with the delay of eFuse memory cells read-out. This kind of partition makes the internal logic of the flip flops (e.g. including the multiplexers 804, 806 in FIG. 8) sufficiently fast to make sure that the slowest part of the pipeline is the actual eFuse memory cell.

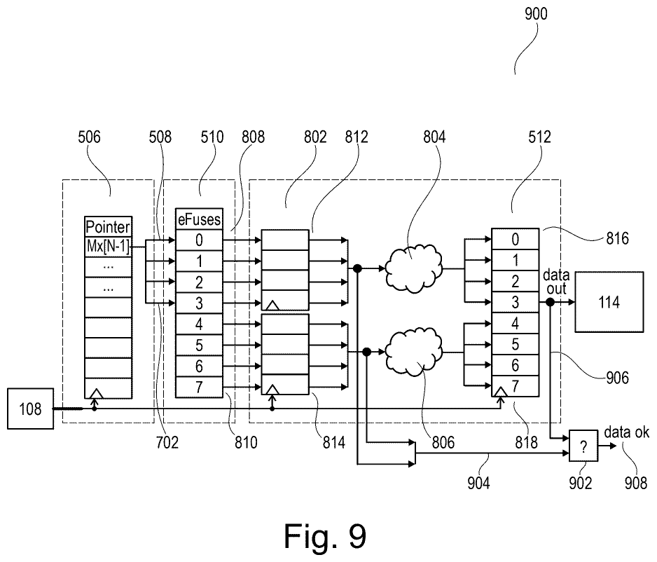

In order to optimize the area utilization (besides the mentioned speed increment), the intermediate registers 802 allow:
to keep the output stable during the entire read-out process; this may be important e.g. when providing trimming/configuration bits to analog blocks such as the electronic components of the IC 106, e.g. the electronic components of the current sense circuit 114 as described above; in the case of short circuit, it may avoid false short circuit detections and may speed up the detection process;
to compare current read-outs with previous read-outs; a margin test may be provided in a production test; instead of comparing the results of both, the normal and the margin read-out at a tester (which would result into higher testing costs), this architecture may enable an automatic comparison by re-using the intermediate registers 802 of the pipeline; this Built-In-Self-Test feature is shown in the FIG. 9.

FIG. 9 shows the portion of an electric fuse memory 800 of FIG. 8 illustrating a built-in self-test in accordance with various aspects of this disclosure.

The built-in self-test may be implemented in a very simple manner, e.g. by providing a comparator 902, a first input of which is coupled to an output of a respective intermediate flip flop of the plurality of intermediate flip flops of the plurality of intermediate registers 802 via a first intermediate connection 904, and a second input of which is coupled to an output of a respective flip flop of the plurality of flip flops of the plurality of registers 512 via a second intermediate connection 906. Thus, the comparator 902 may compare the content of a respective intermediate flip flop of the plurality of intermediate registers 802 with the content of a respective (e.g. an associated) flip flop of the plurality of registers 512. If the respective data (in other words contents) are identical, the data are correct (ok) and a comparison result 908 indicates that the data are correct. In case the respective data (in other words contents) are different from each other, the comparison result 908 indicates that the data are false. Thus, it is possible to verify that parallel reading and serial reading of the eFuse memory cells provides the same results.

In summary, an eFuse memory (e.g. eFuse memory 800 or 900) is provided. The eFuse memory 800 may include a plurality of eFuse memory cells 510, a pointer circuit 506 configured to address one or more eFuse memory cells 510 of the plurality of eFuse memory cells 510, a control circuit 504 configured to control access to the plurality of eFuse memory cells 510, using the pointer circuit 506 to address the one or more eFuse memory cells 510 to access, and a read circuit configured to read the content of the accessed one or more eFuse memory cells 510. The read circuit may include a plurality of output registers 512 and a plurality of intermediate registers 802 coupled between the eFuse memory cells 510 and the output registers 512, wherein the intermediate registers 802 are configured to buffer the content of the accessed one or more eFuse memory cells 510 and to forward the content of the accessed one or more eFuse memory cells 510 to the output registers 512.

The pointer circuit 506 may be configured to address a plurality of eFuse memory cells 510 in parallel. Furthermore, the pointer circuit 506 may be configured to subsequently address one or more eFuse memory cells 510 of all memory cell blocks 1002, 1004, 1006 of the plurality of memory cell blocks 1002, 1004, 1006. The pointer circuit 506 may include or be formed by a shift register.

The control circuit 504 may be configured as a finite state machine.

The eFuse memory 800, 900 may further include a plurality of sense amplifiers, each sense amplifier associated with one or more eFuse memory cells 510 and configured to detect an electric current flowing through an associated eFuse memory cell 510. Each sense amplifier may be coupled to an associated intermediate register 802 to store a value in the associated intermediate register 802 representing the detected electric current flowing through the associated eFuse memory cell 510. Each sense amplifier may be associated with a single eFuse memory cell 510 of the plurality of eFuse fuse memory cells 510.

### 3) Hybrid Centralized Control

Pipelining and parallelizing the read-out increases the throughput of the sensing operation. However, a low latency may also be provided to minimize the overall read-out process. A solution may contain distributed control circuits, e.g. distributed finite state machines (FSMs).

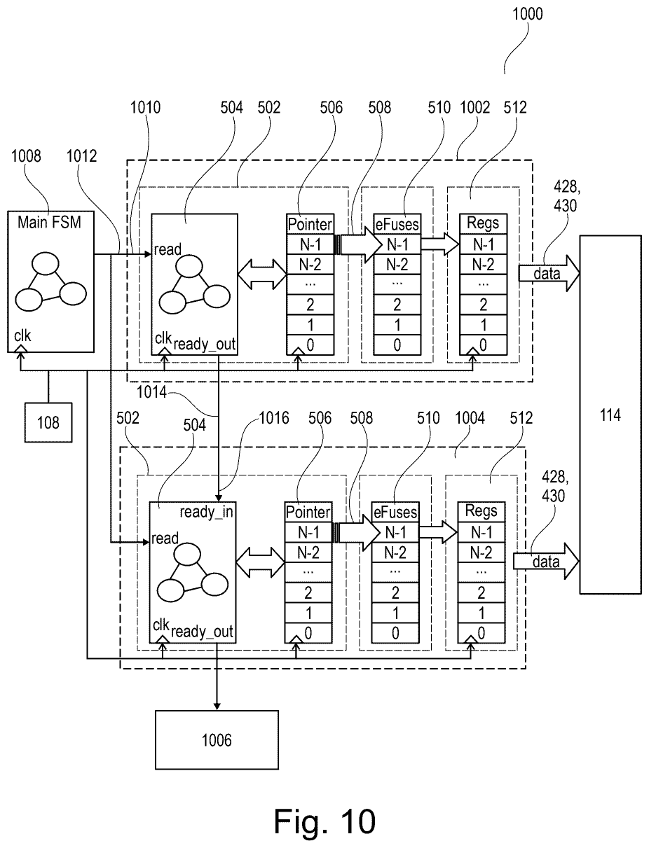

FIG. 10 shows an eFuse memory 1000 in accordance with various aspects of this disclosure. The eFuse memory 1000 of FIG. 10 is an exemplary implementation of the eFuse memory 116 of FIG. 1.

The eFuse memory 1000 may include a plurality of memory cell blocks (e.g. a first memory cell block 1002 and a second memory cell block 1004 and any number of additional memory cell blocks 1006). Each memory cell block 1002, 1004, 1006 of the plurality of memory cell blocks 1002, 1004, 1006 may include a plurality of eFuse memory cells. Each memory cell block 1002, 1004, 1006 may have the same structure as any one of the eFuse memories 500, 700, 800 as described above.

The eFuse memory 1000 may optionally include a main control circuit 1008 coupled to each of the memory cell blocks 1002, 1004, 1006 and may be configured to control the overall operation of (e.g. sequential access to) each of the memory cell blocks 1002, 1004, 1006.

By way of example, in case a read-out process is provided to access (read) eFuse memory cells from a plurality of memory cell blocks 1002, 1004, 1006, the main control circuit 1008 may start the read-out process by generating a read start signal 1010 and apply the same to the control circuit 504 of the first memory cell block 1002 via a first main control connection 1012. The control circuit 504 of the first memory cell block 1002 reads the content of the eFuse memory cells 510 of the first memory cell block 1002 in accordance with the addressing by the pointer circuit 506 of the first memory cell block 1002, stores the read content of the eFuse memory cells 510 in the registers 512 of the first memory cell block 1002 and then transfers the data stored therein to the IC 106, e. g to the current sense circuit 114.

When the first memory cell block 1002 has completed its read-out process, the control circuit 504 of the first memory cell block 1002 generates a read complete signal 1014 and may apply the same to the control circuit 504 of the second memory cell block 1004 via a second main control connection 1016 The control circuit 504 of the second memory cell block 1004 reads the content of the eFuse memory cells 510 of the second memory cell block 1004 in accordance with the addressing of the pointer circuit 506 of the second memory cell block 1004, stores the read content of the eFuse memory cells 510 in the registers 512 of the second memory cell block 1004 and then transfers the data stored therein to the IC 106, e. g to the current sense circuit 114.

This process may be repeated for each provided further memory cell block 1006. When the “last” provided memory cell block 1004, 1006 has completed the read-out process, a complete signal (not shown) may be provided to the main control circuit 1008 which may be configured to then end the read-out process.

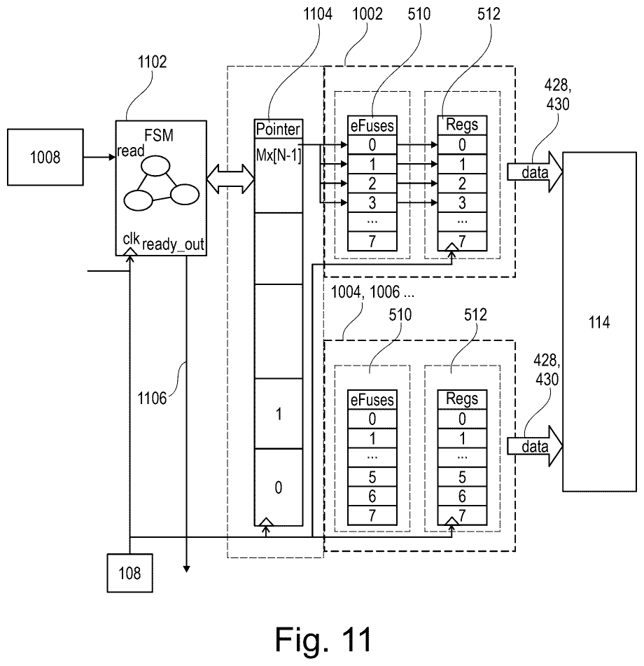

FIG. 11 shows an eFuse memory 1100 in accordance with various aspects of this disclosure illustrating a hybrid centralized control architecture. The eFuse memory 1100 of FIG. 11 is an exemplary implementation of the eFuse memory 116 of FIG. 1.

The eFuse memory 1100 of FIG. 11 is similar to the eFuse memory 1000 of FIG. 10. In order to avoid repetition, only various differences of the eFuse memory 1100 of FIG. 11 to the eFuse memory 1000 of FIG. 10 will be described in more detail in the following. With respect to the similar components, reference is made to the above description of the eFuse memory 1000 of FIG. 10.

Illustratively, in this example, the eFuse memory 1100 has a plurality of memory cell blocks 1002, 1004, 1006, but in addition to the main control circuit 1008, only a single common control circuit 1102 (which may also be referred to as shared control circuit 1102) and a single common pointer circuit 1104 (which may also be referred to as shared pointer circuit 1104) for at least some memory cell blocks of the plurality of memory cell blocks 1002, 1004, 1006 (e.g. for all memory cell blocks 1002, 1004, 1006 of the plurality of memory cell blocks 1002, 1004, 1006). Thus, in other words, the single common control circuit 1102 may be configured to implement and control the programming and reading of the eFuse memory cells of at least some memory cell blocks of the plurality of memory cell blocks 1002, 1004, 1006 (e.g. of all memory cell blocks 1002, 1004, 1006 of the plurality of memory cell blocks 1002, 1004, 1006). Illustratively, the single common control circuit 1102 functionally replaces the plurality of (local) common control circuits 504 of the plurality of memory cell blocks 1002, 1004, 1006. Furthermore, the single common pointer circuit 1104 may be configured to generate the access signals for accessing (and thus illustratively address, thereby activate/deactivate) at least some memory cell blocks of the plurality of memory cell blocks 1002, 1004, 1006 (e.g. of all memory cell blocks 1002, 1004, 1006 of the plurality of memory cell blocks 1002, 1004, 1006). Illustratively, the single common pointer circuit 1104 functionally replaces the plurality of (local) common pointer circuits 506 of the plurality of memory cell blocks 1002, 1004, 1006.

Each memory cell block 1002, 1004, 1006 includes a plurality of eFuse memory cells 510.

Thus, in various aspects, the common pointer circuit 1104 may be configured to access (illustratively address) one or more eFuse memory cells 510 of all memory cell blocks 1002, 1004, 1006 of the plurality of memory cell blocks 1002, 1004, 1006, and the common control circuit 1102 may be configured to control access to the plurality of eFuse memory cells 510 of all memory cell blocks 1002, 1004, 1006 of the plurality of memory cell blocks 1002, 1004, 1006, using the common pointer circuit 1104 to access (illustratively address) the one or more eFuse memory cells 510 to access.

In consequence, at least some memory cell blocks of the plurality of memory cell blocks 1002, 1004, 1006 (e.g. of all memory cell blocks 1002, 1004, 1006 of the plurality of memory cell blocks 1002, 1004, 1006) are free from the (local) control circuit 504 and the (local) pointer circuit 506 (and thus free from the (local) controller 502) as compared with the eFuse memory 1000 of FIG. 10.

As described above, the eFuse memory 1100 may include the read circuit configured to read the content of the accessed one or more eFuse memory cells 510. The read circuit may include the plurality of output registers 512 configured to store the content of the accessed one or more eFuse memory cells 510.

Optionally, the read circuit may include a plurality of intermediate registers (not shown in FIG. 11) coupled between the eFuse memory cells 510 and the output registers 512. As described above, the intermediate registers are configured to buffer the content of the accessed one or more eFuse memory cells 510 and to forward the content of the accessed one or more eFuse memory cells 510 to the output registers 512. It is to be noted that the plurality of intermediate registers may be omitted in various aspects of this disclosure.

The eFuse memory 1100 may further include a plurality of sense amplifiers, each sense amplifier associated with one or more eFuse memory cells 510 and configured to detect an electric current flowing through an associated eFuse memory cell 510. Each sense amplifier is coupled to an associated intermediate register (or to an associated output register 512) to store a value in the associated intermediate register (or in the associated output register 512) representing the detected electric current flowing through the associated eFuse memory cell 510. Each sense amplifier may be associated with a single eFuse memory cell 510 of the plurality of eFuse memory cells 510.

The common pointer circuit 1104 may be configured to access (illustratively address) a plurality of eFuse memory cells 510 in each memory cell block 1002, 1004, 1006 of the plurality of memory cell blocks 1002, 1004, 1006 in parallel. The common pointer circuit 1104 may be configured to subsequently access (illustratively address) one or more eFuse memory cells 510 of all memory cell blocks 1002, 1004, 1006 of the plurality of memory cell blocks 1002, 1004, 1006. The common pointer circuit 1104 may include or be formed by a shift register.

Furthermore, the common control circuit 1102 may be configured as a finite state machine. As shown in FIG. 11, the common control circuit 1102 may be configured to generate and output a access complete signal 1106 to indicate that the access operation to the eFuse memory cells 510 of one or more memory cell blocks 1002, 1004, 1006 has been completed.

An advantage of this distributed control is that the data is organized in a natural manner, where each memory cell block 1002, 1004, 1006 contains a certain number of eFuse memory cells 510 which fits the actual needs of the system. Handling a memory with a word size which fits the requirements of the system simplifies memory handling.

The hybrid control keeps the advantages of a properly organized eFuse memory structure with the low latency of a fully centralized eFuse memory structure.

By centralizing the control structure using a unique pointer circuit (e.g. the common pointer circuit 1104) for all the memory cell block (e.g. memory cell block 1002, 1004, 1006) and removing the distributed finite state machines, the latency decreases and the implementation gets simplified.

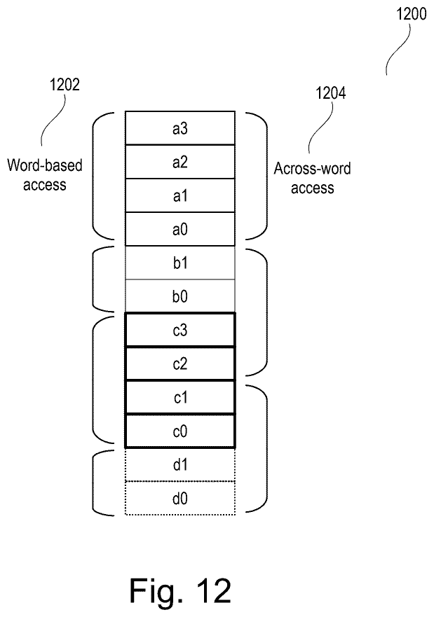

It is to be noted that this type of control allows to access the eFuse memory across different memory words, as shown in the FIG. 12.

FIG. 12 illustrates an eFuse memory access across a plurality of memory words in accordance with various aspects of this disclosure (which may also be referred to as a hybrid eFuse memory access across memory words) in a diagram 1200.

In various aspects, a single memory word may be stored in each memory cell block of the plurality of memory cell blocks 1002, 1004, 1006.

By way of example, FIG. 12 shows a first memory word having four bits (a0, a1, a2, a3), a second memory word having two bits (b0, b1), a third memory word having four bits (c0, c1, c2, c3) and a fourth memory word having two bits (d0, d1).

In a conventional memory word-based memory access (illustrated on the left hand side of FIG. 12 with reference 1202), the number of memory accesses needed in the previous example is four, while the hybrid control memory needs only three accesses (illustrated on the right hand side of FIG. 12 with reference 1204).

It is to be noted that the memory access in these examples is sequential. The order of the registers (a (a first plurality of flip flops of a first register of a first memory cell block (storing the first memory word (a0, a1, a2, a3))), b (a second plurality of flip flops of a second register b of a second memory cell block (storing the second memory word (b0, b1))), c (a third plurality of flip flops of a third register c of a third memory cell block (storing the third memory word (c0, c1, c2, c3))) and d (a fourth plurality of flip flops of a fourth register d of a fourth memory cell block (storing the fourth memory word (d0, d1))) in the example) is selected in terms of timing priorities: the flip flops of the first register (at location 0) is the one that is read first. By doing this, the eFuse memory makes sure that the value that is going to be used first by the system will be updated first.

In the following, various aspects of this disclosure will be illustrated:

Example 1 is an electric fuse, eFuse, memory. The eFuse memory may include a plurality of memory cell blocks, each memory cell block of the plurality of memory cell blocks including a plurality of electric fuse memory cells, a pointer circuit configured to address one or more electric fuse memory cells of all memory cell blocks of the plurality of memory cell blocks, and a control circuit configured to control access to the plurality of electric fuse memory cells of all memory cell blocks of the plurality of memory cell blocks, using the pointer circuit to address the one or more electric fuse memory cells to access.

In Example 2, the subject matter of Example 1 can optionally include that the eFuse memory further includes a read circuit configured to read the content of the accessed one or more electric fuse memory cells.

In Example 3, the subject matter of Example 2 can optionally include that the read circuit includes one or more (e.g. a plurality of) output registers configured to store the content of the accessed one or more electric fuse memory cells.

In Example 4, the subject matter of Example 3 can optionally include that the read circuit further includes a plurality of intermediate registers coupled between the electric fuse memory cells and the output registers. The intermediate registers are configured to buffer the content of the accessed one or more electric fuse memory cells and to forward the content of the accessed one or more electric fuse memory cells to the output registers. It is to be noted that the intermediate registers may have a dual functionality: as pipeline registers to speed up the throughput and as intermediate registers to store the previous readout.

In Example 5, the subject matter of Example 4 can optionally include that the eFuse memory further includes a plurality of sense amplifiers, each sense amplifier associated with one or more electric fuse memory cells and configured to detect an electric current flowing through an associated electric fuse memory cell. Each sense amplifier is coupled to an associated intermediate register to store a value in the associated intermediate register representing the detected electric current flowing through the associated electric fuse memory cell.

In Example 6, the subject matter of Example 5 can optionally include that each sense amplifier is associated with a single electric fuse memory cell of the plurality of electric fuse memory cells.

In Example 7, the subject matter of any one of Examples 1 to 6 can optionally include that the pointer circuit is configured to access (illustratively address) a plurality of electric fuse memory cells in each memory cell block of the plurality of memory cell blocks in parallel.

In Example 8, the subject matter of any one of Examples 1 to 7 can optionally include that the pointer circuit is configured to subsequently access (illustratively address) one or more electric fuse memory cells of all memory cell blocks of the plurality of memory cell blocks.

In Example 9, the subject matter of Example 8 can optionally include that the pointer circuit includes or is formed by a shift register.

In Example 10, the subject matter of any one of Examples 1 to 9 can optionally include that the control circuit is configured as a finite state machine.

Example 11 is an electric fuse, eFuse, memory. The eFuse memory may include a plurality of electric fuse memory cells, a pointer circuit configured to access (illustratively address) one or more electric fuse memory cells of the plurality of electric fuse memory cells, a control circuit configured to control access to the plurality of electric fuse memory cells, using the pointer circuit to access (illustratively address) the one or more electric fuse memory cells to access, and a read circuit configured to read the content of the accessed one or more electric fuse memory cells. The read circuit may include a plurality of output registers and a plurality of intermediate registers coupled between the electric fuse memory cells and the output registers. The intermediate registers are configured to buffer the content of the accessed one or more electric fuse memory cells and to forward the content of the accessed one or more electric fuse memory cells to the output registers.

In Example 12, the subject matter of Example 11 can optionally include that the pointer circuit is configured to access (illustratively address) a plurality of electric fuse memory cells in parallel.

In Example 13, the subject matter of any one of Examples 11 or 12 can optionally include that the pointer circuit is configured to subsequently access (illustratively address) one or more electric fuse memory cells of all electric fuse memory cells of the plurality of electric fuse memory cells.

In Example 14, the subject matter of Example 13 can optionally include that the pointer circuit includes a shift register.

In Example 15, the subject matter of any one of Examples 11 to 14 can optionally include that the control circuit is configured as a finite state machine.

In Example 16, the subject matter of any one of Examples 11 to 15 can optionally include that the eFuse memory further includes a plurality of sense amplifiers, each sense amplifier associated with one or more electric fuse memory cells and configured to detect an electric current flowing through an associated electric fuse memory cell. Each sense amplifier is coupled to an associated intermediate register to store a value in the associated intermediate register representing the detected electric current flowing through the associated electric fuse memory cell.

In Example 17, the subject matter of Example 16 can optionally include that each sense amplifier is associated with a single electric fuse memory cell of the plurality of electric fuse memory cells.

Example 18 is a power switch circuit arrangement. The power switch circuit arrangement may include a power switch circuit, a circuit configured to control the power switch circuit, and an electric fuse memory of any one of Examples 1 to 17.

In Example 19, the subject matter of Example 18 can optionally include that the power switch circuit arrangement further includes a control terminal driver circuit. The circuit is coupled between the control terminal driver circuit and the power switch circuit.

In Example 20, the subject matter of any one of Examples 18 or 19 can optionally include that the power switch circuit includes a power switch transistor.

In Example 21, the subject matter of Example 20 can optionally include that the power switch transistor is a bipolar transistor. The control terminal driver circuit is a base driver circuit.

In Example 22, the subject matter of Example 20 can optionally include that the power switch transistor is a field effect transistor. The control terminal driver circuit is a gate driver circuit.

In Example 23, the subject matter of Example 22 can optionally include that the power switch transistor is a silicon carbide field effect transistor.

In Example 24, the subject matter of any one of Examples 18 to 23 can optionally include that the power switch circuit arrangement further includes a current sense circuit configured to sense a current flowing through the power switch circuit.

In Example 25, the subject matter of any one of Examples 18 to 24 can optionally include that the power switch circuit further includes a current sense power transistor coupled in parallel to the power switch transistor.

In Example 26, the subject matter of Example 25 can optionally include that the current sense power transistor is of the same transistor type as the power switch transistor.

In Example 27, the subject matter of any one of Examples 25 or 26 can optionally include that the current sense power transistor is a bipolar transistor

In Example 28, the subject matter of any one of Examples 25 or 26 can optionally include that the current sense power transistor is a field effect transistor

In Example 29, the subject matter of Example 28 can optionally include that the current sense power transistor is a silicon carbide field effect transistor;

In Example 30, the subject matter of any one of Examples 25 to 29 can optionally include that the current sense circuit is configured to sense an electric current flowing through the current sense power transistor.

In Example 31, the subject matter of any one of Examples 18 to 30 can optionally include that the circuit is configured to detect a short circuit event in the power switch circuit using a read content of one or more electric fuse memory cells.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An electric fuse memory, comprising:
a plurality of memory cell blocks, each memory cell block of the plurality of memory cell blocks comprising a plurality of electric fuse memory cells;
a pointer circuit configured to address one or more electric fuse memory cells of all memory cell blocks of the plurality of memory cell blocks; and
a control circuit configured to control access to the plurality of electric fuse memory cells of all memory cell blocks of the plurality of memory cell blocks, using the pointer circuit to address the one or more electric fuse memory cells to access.

2. The electric fuse memory of claim 1, further comprising:
a read circuit configured to read the content of the one or more electric fuse memory cells.

3. The electric fuse memory of claim 2,
wherein the read circuit comprises one or more output registers configured to store the content of the one or more electric fuse memory cells.

4. The electric fuse memory of claim 3,
wherein the read circuit further comprises a plurality of intermediate registers coupled between the plurality of electric fuse memory cells and the one or more output registers, wherein the plurality of intermediate registers are configured to buffer the content of the one or more electric fuse memory cells and to forward the content of the one or more electric fuse memory cells to the one or more output registers.

5. The electric fuse memory of claim 4, further comprising:
a plurality of sense amplifiers, each sense amplifier associated with one or more electric fuse memory cells and configured to detect an electric current flowing through an associated electric fuse memory cell;
wherein each sense amplifier is coupled to an associated intermediate register to store a value in the associated intermediate register representing the detected electric current flowing through the associated electric fuse memory cell.

6. The electric fuse memory of claim 5,
wherein each sense amplifier is associated with a single electric fuse memory cell of the plurality of electric fuse memory cells.

7. The electric fuse memory of claim 1,
wherein the pointer circuit is configured to address a plurality of electric fuse memory cells in each memory cell block of the plurality of memory cell blocks in parallel.

8. The electric fuse memory of claim 1,
wherein the pointer circuit is configured to subsequently address one or more electric fuse memory cells of all memory cell blocks of the plurality of memory cell blocks.

9. The electric fuse memory of claim wherein the pointer circuit comprises a shift register.

10. The electric fuse memory of claim 1,
wherein the control circuit is configured as a finite state machine.

11. A power switch circuit arrangement, comprising:
a power switch circuit;
a circuit configured to control the power switch circuit; and
an electric fuse memory comprising:
a plurality of memory cell blocks, each memory cell block of the plurality of memory cell blocks comprising a plurality of electric fuse memory cells;
a pointer circuit configured to address one or more electric fuse memory cells of all memory cell blocks of the plurality of memory cell blocks; and
a control circuit configured to control access to the plurality of electric fuse memory cells of all memory cell blocks of the plurality of memory cell blocks, using the pointer circuit to address the one or more electric fuse memory cells to access.

12. The power switch circuit arrangement of claim 11, further comprising:
a control terminal driver circuit;
wherein the circuit is coupled between the control terminal driver circuit and the power switch circuit.

13. The power switch circuit arrangement of claim 11,
wherein the power switch circuit comprises a power switch transistor.

14. The power switch circuit arrangement of claim 13,
wherein the power switch transistor is a field effect transistor; and
wherein the control terminal driver circuit is a gate driver circuit.

15. The power switch circuit arrangement of claim 14,
wherein the power switch transistor is a silicon carbide field effect transistor.

16. The power switch circuit arrangement of claim 13, further comprising:
a current sense circuit configured to sense a current flowing through the power switch circuit.

17. The power switch circuit arrangement of claim 16,
wherein the power switch circuit further comprises a current sense power transistor coupled in parallel to the power switch transistor.

18. The power switch circuit arrangement of claim 17,
wherein the current sense power transistor is a field effect transistor.

19. The power switch circuit arrangement of claim 18,
wherein the current sense power transistor is a silicon carbide field effect transistor.

20. The power switch circuit arrangement of claim 16,
wherein the current sense circuit is configured to sense an electric current flowing through the current sense power transistor.

21. The power switch circuit arrangement of claim 11,
wherein the circuit is configured to detect a short circuit event in the power switch circuit using a read content of one or more electric fuse memory cells.
